(19) United States
(12) Patent Application Publication
(10) Pub. No.: US 2026/0110976 A1
(43) Pub. Date: Apr. 23, 2026

(54) SYSTEM AND METHOD FOR MEASURING CRITICAL DIMENSIONS USING TILT-BASED REFLECTOMETRY

(71) Applicant: KLA Corporation, Milpitas, CA (US)

(72) Inventors: Janardan Nath, Milpitas, CA (US); Phillip R. Atkins, San Jose, CA (US); Jinchuan Shi, Milpitas, CA (US); Shankar Krishnan, Cupertino, CA (US)

(21) Appl. No.: 19/338,397

(22) Filed: Sep. 24, 2025

Related U.S. Application Data
(60) Provisional application No. 63/708,260, filed on Oct. 17, 2024.

(51) Int. Cl. G03F 7/00

(52) U.S. Cl. CPC G03F 7/70625; G03F 7/706839; G03F 7/706845; G03F 7/706849; G03F 7/706851

(57) ABSTRACT

A metrology system includes an illumination source generating illumination beams. Illumination optics direct the beams to a sample surface at non-zero incidence angles. Detectors collect light from the sample surface, with collection optics directing this light to the detectors. A controller with processors executes program instructions to receive metrology data from detectors based on collected light. The metrology data includes measurements at multiple tilt angles based on non-zero incidence. The processors determine a bottom critical dimension value at zero-degree incidence by extrapolating measurement data collected at the multiple tilt angles.

### CROSS-REFERENCE TO RELATED APPLICATIONS

The present application claims the benefit under 35 U.S.C. § 119(e) of U.S. Provisional Application Ser. No. 63/708,260, filed Oct. 17, 2024, which is incorporated herein by reference in the entirety.

### TECHNICAL FIELD

The present disclosure relates generally to metrology systems and methods, and more particularly to, systems and methods for measuring critical dimensions using tilt-based reflectometry.

### BACKGROUND

Semiconductor manufacturing processes increasingly rely on advanced three-dimensional structures, such as through-silicon vias (TSVs), to achieve higher device densities and improved electrical performance. These structures present measurement challenges due to their high aspect ratios and complex geometries, where accurate characterization of critical dimensions at various depths is important for process control and yield optimization.

Current optical metrology systems typically operate under normal incidence conditions, where illumination is directed perpendicular to the sample surface. However, these conventional measurement approaches create sensitivity limitations when attempting to characterize bottom features of deep structures. For example, the normal incidence conditions provide insufficient optical contrast to distinguish between top and bottom critical dimensions due to limited light penetration and interaction with sidewall and bottom surfaces of high aspect ratio structures. Additionally, specular reflection from top surfaces can dominate the collected signal, masking weaker signals from bottom features. As such, these sensitivity constraints can result in measurement uncertainty and reduced capability to monitor process variations that affect the structural integrity and electrical performance of advanced semiconductor devices.

There is therefore a need for a system and method which cures one or more shortfalls of the previous approaches.

### SUMMARY

A metrology system is disclosed, in accordance with one or more embodiments of the present disclosure. In embodiments, the metrology system includes an illumination source configured to generate one or more illumination beams, one or more illumination optics configured to direct the one or more illumination beams to a surface of a sample disposed on a sample stage, the one or more illumination beams having a non-zero angle of incidence with respect to the surface of the sample, one or more detectors configured to collect light emanated from the surface of the sample, one or more collection optics configured to direct the light emanated from the surface of the sample to the one or more detectors, and a controller communicatively coupled to the one or more detectors. The controller includes one or more processors configured to execute a set of program instructions stored in memory. The set of program instructions are configured to cause the one or more processors to receive a set of metrology data from the one or more detectors based on the collected light, the set of metrology data including metrology measurement data collected at a plurality of tilt angles based on the non-zero angle of incidence, and determine a bottom critical dimension value at zero-degree angle of incidence by extrapolating the measurement data collected at the plurality of tilt angles based on the non-zero angle of incidence.

In some embodiments, the metrology system may further include the sample stage.

In some embodiments, the sample stage may include a multi-axis tilting stage configured to tilt the sample in at least one of an x-direction or a y-direction based on the plurality of tilt angles.

In some embodiments, the one or more illumination optics may include one or more adjustable beam steering components configured to direct the one or more illumination beams at one or more predetermined non-zero angles relative to a surface normal of the sample.

In some embodiments, the plurality of tilt angles may be between 10 arcseconds and 50 arcseconds.

In some embodiments, the metrology system may include a spectral reflectometry metrology system configured to measure reflectance information that varies as a function of wavelength.

In some embodiments, the sample may include a substrate.

In some embodiments, the substrate may include a wafer.

In some embodiments, the one or more processors may be configured to apply one or more linear fitting algorithms to extrapolate the measurement data, the one or more linear fitting algorithms including linear polarization analysis algorithms that analyze polarization-dependent spectral signatures obtained at the plurality of tilt angles.

In some embodiments, the one or more processors may be further configured to compare spectral signatures obtained at the plurality of tilt angles to identify spectral delta patterns, flat bottom structures exhibiting larger spectral deltas compared to rounded bottom structures.

A system is disclosed, in accordance with one or more embodiments of the present disclosure. In embodiments, the system includes a controller communicatively coupled to a metrology sub-system. The controller includes one or more processors configured to execute a set of program instructions stored in memory. The set of program instructions are configured to cause the one or more processors to receive a set metrology data from the metrology sub-system, the set of metrology data including metrology measurement data for a sample disposed on a sample stage collected at a plurality of tilt angles based on a non-zero angle of incidence, and determine a bottom critical dimension value at zero-degree angle of incidence by extrapolating the set of measurement data collected at the plurality of tilt angles based on the non-zero angle of incidence.

In some embodiments, the system may further include an illumination sub-system. The illumination sub-system may include an illumination source configured to generate one or more illumination beams and one or more illumination optics configured to direct the one or more illumination beams to a surface of the sample, one or more illumination beams having the non-zero angle of incidence with respect to the surface of the sample.

In some embodiments, the system may further include a collection sub-system. The collection sub-system may include one or more detectors configured to collect light emanated from the surface of the sample and one or more collection optics configured to direct the light emanated from the surface of the sample to the one or more detectors.

In some embodiments, the system may further include the sample stage, the sample stage including a multi-axis tilting stage configured to tilt the sample in at least one of an x-direction or a y-direction based on the plurality of tilt angles.

In some embodiments, the one or more illumination optics may include one or more adjustable beam steering components configured to direct the one or more illumination beams at one or more predetermined non-zero angles relative to a surface normal of the sample.

In some embodiments, the plurality of tilt angles may be between 10 arcseconds and 50 arcseconds.

In some embodiments, the metrology sub-system may include a spectral reflectometry metrology system configured to measure reflectance information that varies as a function of wavelength.

In some embodiments, the sample may include a substrate.

In some embodiments, the substrate may include a wafer.

In some embodiments, the one or more processors may be configured to apply one or more linear fitting algorithms to extrapolate the measurement data, the one or more linear fitting algorithms including linear polarization analysis algorithms that analyze polarization-dependent spectral signatures obtained at the plurality of tilt angles.

In some embodiments, the one or more processors may be further configured to compare spectral signatures obtained at the plurality of tilt angles to identify spectral delta patterns, flat bottom structures exhibiting larger spectral deltas compared to rounded bottom structures.

A method is disclosed, in accordance with one or more embodiments of the present disclosure. In embodiments, the method includes generating one or more illumination beams, directing the one or more illumination beams to a surface of a sample disposed on a sample stage, the one or more illumination beams having a non-zero angle of incidence with respect to the surface of the sample, directing light emanating from the surface of the sample to one or more detectors, collecting light emanated from the surface of the sample using the one or more detectors, receiving a set metrology data from the one or more detectors based on the collected light, the set of metrology data including metrology measurement data collected at a plurality of tilt angles based on the non-zero angle of incidence, and determining a bottom critical dimension value at zero-degree angle of incidence by extrapolating the set of metrology data collected at the plurality of tilt angles based on the non-zero angle of incidence.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1 illustrates a simplified block diagram of a tilt-based reflectometry system, in accordance with one or more embodiments of the present disclosure.

FIG. 2A illustrates a simplified schematic diagram of a metrology sub-system of the tilt-based reflectometry system, in accordance with one or more embodiments of the present disclosure.

FIG. 2B illustrates a simplified schematic diagram of the metrology sub-system of the tilt-based reflectometry system, in accordance with one or more embodiments of the present disclosure.

FIG. 3A illustrates a plot showing flat spectra delta measurements at different angles of incidence, in accordance with one or more embodiments of the present disclosure.

FIG. 3B illustrates a plot showing round spectra delta measurements at different angles of incidence, in accordance with one or more embodiments of the present disclosure.

FIG. 4 illustrates a flowchart depicting a method for measuring bottom critical dimensions, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to a tilt-based reflectometry system and method for measuring critical dimensions in semiconductor structures. For example, the system and method may measure bottom critical dimensions (BCDs) in high aspect ratio (HAR) structures, such as Through Silicon Vias (TSVs), based on a plurality of measurements generated at a plurality of tilt angles, whereby tilting the sample or illumination beam introduces an angle of incidence (AOI) during reflectivity measurements. In this regard, such tilted configuration allows light to interact with the sidewalls and bottom surfaces of the HAR structure of the sample, such that distinguishable spectral signatures are generated. As such, the BCDs may be differentiated from the top CDs (TCDs). As previously mentioned herein, conventional systems utilize a zero-degree incidence configuration (e.g., normal incidence). In such systems, the zero-degree measurements lack sufficient sensitivity to differentiate between top and bottom critical dimensions.

For purposes of the present disclosure, the term “zero-degree incidence” or “normal incidence” may refer to a measurement configuration where illumination beams are directed perpendicular to the surface of a sample, such that the angle between the incident beam and the surface normal is zero degrees. In normal incidence conditions, light rays may travel along a path that is substantially orthogonal to the sample surface plane, creating a measurement geometry where the illumination and collection optical paths may be coaxial or nearly coaxial. This configuration may be contrasted with angled or tilted incidence measurements, where the illumination beam approaches the sample surface at a non-zero angle relative to the surface normal.

The system and method of the present disclosure collects spectral data at multiple tilt angles, which may be analyzed and extrapolated to determine bottom critical dimension values at zero-degree incidence, thus enabling accurate measurement of BCDs in HAR structures.

In addition to enabling accurate measurement of BCDs, the system and method of the present disclosure may provide several other advantages over conventional normal incidence systems. For example, the system and method of the present disclosure may improve the optical sensitivity to sidewall characteristics of high aspect ratio structures, allowing for improved measurement of sidewall angles, roughness, and profile variations that may affect device performance. In some cases, the tilted measurement geometry may reduce the impact of surface contamination or thin film interference effects that can obscure measurements in normal incidence configurations. The system and method of the present disclosure may also provide improved measurement repeatability and reduced noise in certain measurement scenarios, as the angled illumination can minimize specular reflection artifacts that may occur with perpendicular incidence. Further, the multi-angle measurement approach may enable better decorrelation of various structural parameters, such as TCD, BCD, and sidewall profile characteristics, thereby providing more comprehensive structural characterization in a single measurement sequence. It is contemplated herein that the tilt-based methodology may also extend the measurement capability to structures with varying aspect ratios and geometries, where conventional normal incidence approaches may lack sufficient sensitivity or contrast.

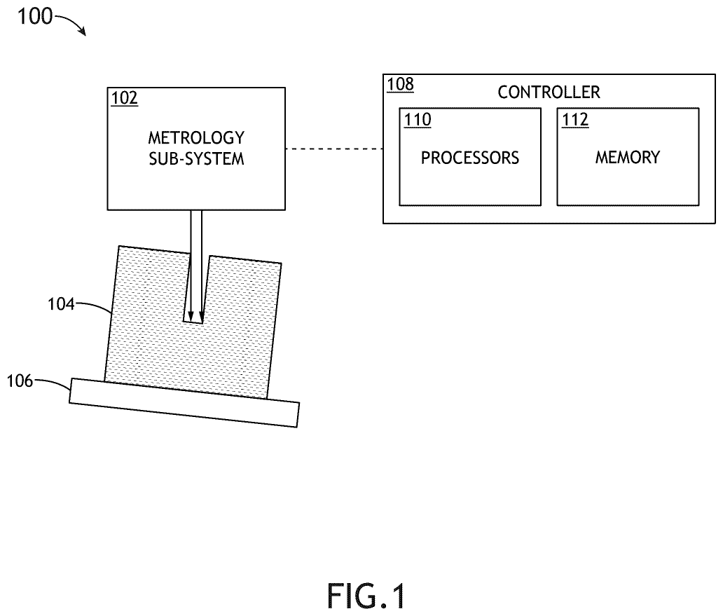

FIGS. 1-4 generally illustrate a system and method for measuring critical dimensions using tilt-based reflectometry, in accordance with one or more embodiments of the present disclosure.

FIG. 1 illustrates a simplified block diagram of a tilt-based reflectometry system 100, in accordance with one or more embodiments of the present disclosure.

In embodiments, the system 100 may be configured to perform metrology measurements on a sample 104 using tilt-based reflectometry techniques. The system 100 may include a metrology sub-system 102 configured to measure the sample 104 disposed on a sample stage 106. For example, the metrology sub-system 102 may be configured to perform multiple measurements at a plurality of tilt angles, where either the sample 104 or an illumination beam is oriented at a non-zero angle of incidence (AOI) relative to the sample surface, thereby enabling accurate measurement of bottom critical dimensions (BCDs) by introducing controlled angular variations during the measurement process (as will be discussed further herein).

For purposes of the present disclosure, the term “non-zero angles of incidence” may refer to measurement configurations where illumination beams approach the sample surface at angles other than perpendicular, creating an angular deviation from the surface normal that is greater than zero degrees. Under non-zero AOI conditions, the incident light rays may be directed toward the sample surface along paths that are tilted or angled relative to the vertical axis perpendicular to the sample plane. This angular orientation may be achieved by tilting either the sample relative to the illumination beam or by directing the illumination beam at an angle relative to the sample surface. The non-zero AOI may range from small angular deviations of a few arcseconds to larger angles of several degrees, depending on the specific measurement requirements and structural characteristics of the sample being analyzed, as will be discussed further herein.

The metrology sub-system 102 may be communicatively coupled to one or more controllers 108 including one or more processors 110 and memory 112. The one or more processors 110 may be configured to perform one or more steps in accordance with a set of program instructions stored in the memory 112. For example, the one or more controllers 108 may be configured to control one or more operations of the system 100 and receive and analyze measurement data obtained from the sample 104. In this regard, the one or more controllers 108 may control the operation of the metrology sub-system 102 and the sample stage 106 to perform tilt-based reflectometry measurements at multiple angular positions. Further, the one or more controllers 108 may analyze the collected measurement data from the metrology sub-system 102 to extract BCD information through analysis and extrapolation techniques, as will be discussed further herein.

In embodiments, the sample stage 106 may be communicatively coupled to the one or more controllers 108 to enable precise control of the angular positioning during tilt-based reflectometry measurements. For example, the one or more controllers 108 may be configured to provide one or more control signals to the sample stage 106 to adjust the position and orientation of the sample 104 according to predetermined measurement sequences (e.g., predetermined tilt angles or AOIs) or real-time analysis requirements. For instance, the one or more controllers 108 may execute the set of program instructions stored in the memory 112 to coordinate the positioning of the sample stage 106 with the operation of the metrology sub-system 102, thereby ensuring synchronized measurement acquisition at specific tilt angles.

In embodiments, the one or more controllers 108 may be configured to control the sample stage 106 positioning through various control mechanisms that enable precise angular adjustments. For example, the one or more controllers 108 may implement closed-loop control algorithms that utilize position feedback from the sample stage 106 to maintain accurate angular positioning throughout the measurement process. In one instance, the one or more controllers 108 may be configured to adjust the sample stage 106 position based on measurement data analysis, where the one or more processors 110 may determine predetermined tilt angles associated with specific structural characteristics or measurement objectives. In another instance, the one or more controllers 108 may be configured to execute automated measurement sequences that involve moving the sample stage 106 through a series of predetermined angular positions while coordinating data collection from the metrology sub-system 102.

The memory 112 may store program instructions, measurement data, and analysis algorithms utilized by the one or more processors 110. In some cases, the memory 112 may contain software modules for controlling the metrology sub-system 102, managing sample stage 106 positioning, and processing spectral reflectometry data collected at various tilt angles. The memory 112 may also store calibration data, measurement parameters, and reference information used during the analysis of bottom critical dimensions. The one or more processors 110 may access the memory 112 to retrieve program instructions and execute measurement sequences, data analysis routines, and system control functions. The combination of the one or more processors 110 and memory 112 may enable the controller 108 to perform complex data processing operations, including extrapolation algorithms that determine bottom critical dimension values based on measurements collected at multiple tilt angles.

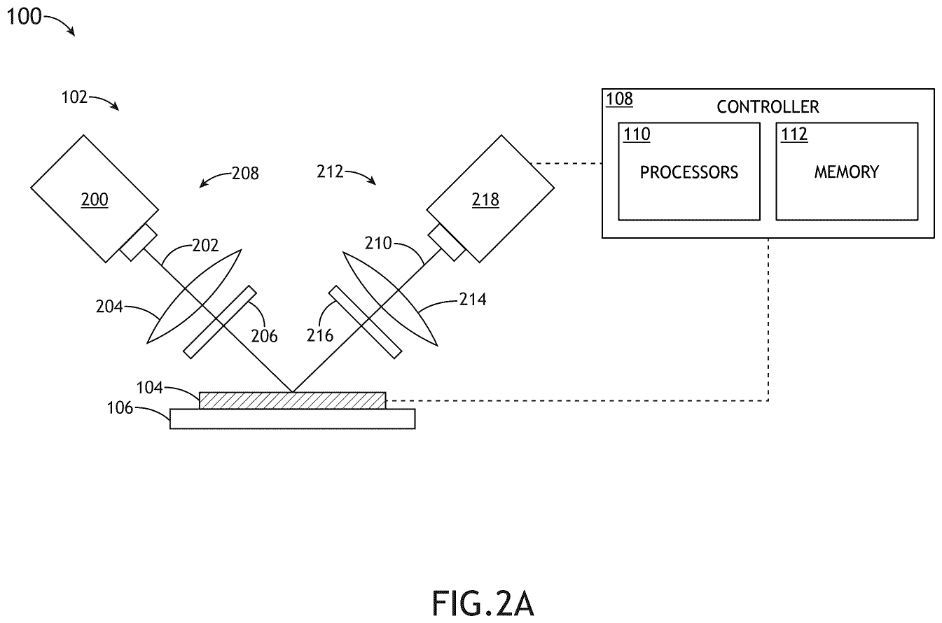

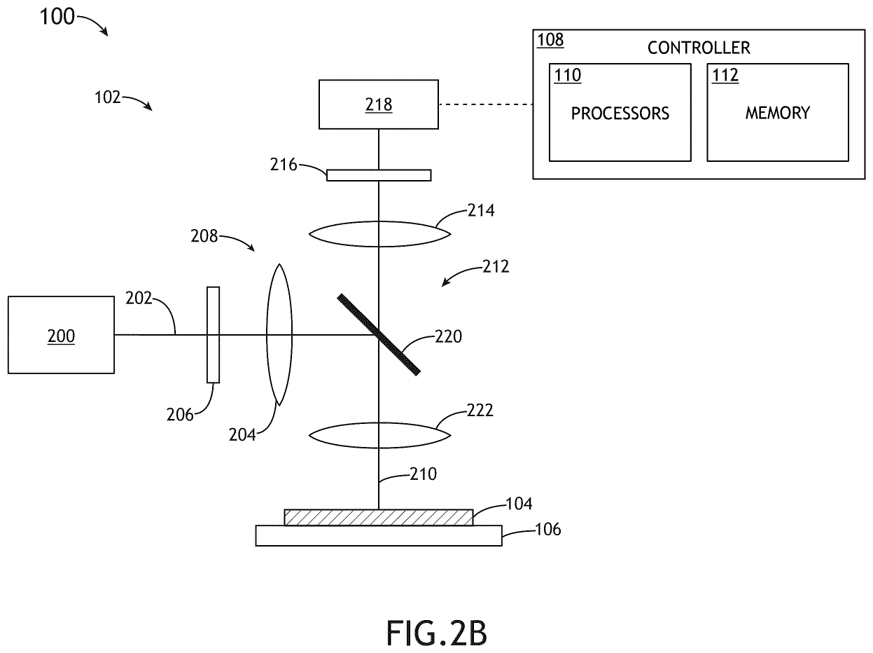

FIGS. 2A-2B illustrate simplified schematics of the metrology sub-system 102 configured to measure the sample 104 positioned on the sample stage 106, in accordance with one or more embodiments of the present disclosure. Referring generally to FIGS. 2A-2B, the metrology sub-system 102 may be configured as a spectral reflectometry metrology system that enables tilt-based measurements for determining BCDs in high aspect ratio structures.

In embodiments, the metrology sub-system 102 may include an illumination source 200 configured to generate one or more illumination beams 202. The illumination source 200 may include any illumination source suitable for spectral reflectometry such as, but not limited to, broadband sources, laser sources, or the like that provide illumination across a range of wavelengths. In some cases, the illumination source 200 may be configured to generate coherent or partially coherent light that enables precise spectral measurements of the sample 104. The illumination beam 202 generated by the illumination source 200 may propagate along an illumination pathway 208 that directs the illumination beam 202 toward the sample 104.

The sample 104 may include any type of semiconductor substrate suitable for tilt-based reflectometry measurements. For example, the sample 104 may include a wafer. For instance, the wafer may include one or more high aspect ratio structures such as, but not limited to, Through Silicon Vias (TSVs), deep trenches, contact holes, or the like. The wafer 104 may include, but is not limited to, a silicon (Si) wafer, a gallium arsenide (GaAs) wafer, an indium phosphide (InP) wafer, a silicon carbide (SiC) wafer, or the like. The sample 104 may also include memory device structures such as NAND flash memory with deep word line trenches or DRAM capacitor structures that require accurate bottom critical dimension measurements for process control and yield optimization. The sample 104 may further include advanced packaging substrates containing redistribution layers (RDL) with embedded vias, or interposer structures with through-substrate interconnects.

The metrology sub-system 102 may further include one or more illumination optics configured to direct the one or more illumination beams 202 to a surface of the sample 104, where the one or more illumination beams 202 may have an angle of incidence with respect to the surface of the sample 104. As shown in FIGS. 2A-2B, the illumination pathway 208 may include an illumination focusing element 204 that focuses or collimates the illumination beam 202 to achieve appropriate beam characteristics for the measurement. The illumination pathway 208 may also include one or more illumination beam conditioning components 206 that may modify various properties of the illumination beam 202 such as, but not limited to, polarization, spectral content, beam size, angular distribution, or the like. In some cases, the illumination beam conditioning components 206 may include polarizers, filters, apertures, or other optical elements that adjust the illumination beam 202 for tilt-based reflectometry measurements.

In embodiments, the one or more controlled angular variations may be implemented during the measurement process by introducing a tilt between the illumination beam 202 and the sample 104. As will be discussed further herein, the tilt may be achieved through various approaches that modify the geometric relationship between the incident illumination and the sample surface. In some cases, the tilt may enable the illumination beam 202 to interact with structural features of the sample 104 in ways that provide enhanced sensitivity to the BCDs compared to conventional normal incidence measurements, where AOI=0. As previously mentioned herein, the controlled angular variations may be adjusted to change the spectral signatures obtained from high aspect ratio structures, thereby improving the accuracy and reliability of BCD measurements.

In some embodiments, the predetermined AOI may be achieved by physically tilting the sample 104 relative to the illumination beam 202, thereby changing the geometric relationship between the incident light and the sample surface. For example, the sample stage 106 may be configured as a multi-axis tilting stage assembly that enables predetermined angular positioning of the sample 104 during the tilt-based reflectometry measurements. For instance, the sample stage 106 may be configured to tilt the sample 104 in at least one of the x-direction or the y-direction to achieve the predetermined AOI for the illumination beam 202, where the one or more controllers 108 may be configured to control the positioning of the sample stage 106 accordingly. In this regard, the metrology sub-system 102 may be configured to measure the sample 104 at multiple tilt angles.

It is contemplated herein that the sample stage 106 may provide control precision precise angular positioning, thus enabling the system 100 to achieve fine angular resolution needed for accurate BCD measurements. For example, the sample stage 106 may be adjusted by +/−1 arcsecond. In this regard, such controlled precision may enable the system 100 to perform measurements at closely spaced angular intervals, thereby providing detailed information about the angular dependence of spectral signatures associated with the BCDs. In some cases, the high precision positioning capability may also enable the system 100 to return to specific angular positions with high repeatability, which may be beneficial for comparative measurements or calibration procedures.

The tilt angle of the sample stage 106 may be adjusted between 1-2000 arcseconds. In a non-limiting example, a first measurement may be taken at a first tilt angle of 50 arcseconds, a second measurement may be taken at a second tilt angle of 40 arcseconds, a third measurement may be taken at a third tilt angle of 30 arcseconds, a fourth measurement may be taken at a fourth tilt angle of 20 arcseconds, and a fifth measurement may be taken at a fifth tilt angle of 10 arcseconds. By way of another non-limiting example, the tilt angle may be adjusted by intervals of 5 arcseconds, where a first measurement may be taken at a first tilt angle of 50 arcseconds, a second measurement may be taken at a second tilt angle of 45 arcseconds, a third measurement may be taken at a third tilt angle of 40 arcseconds, a fourth measurement may be taken at a fourth tilt angle of 35 arcseconds, and a fifth measurement may be taken at a fifth tilt angle of 30 arcseconds. It is contemplated herein that specific angular positions may be selected based on the structural characteristics of the sample 104 and the measurement objectives for particular applications. For example, the sample stage 106 may position the sample 104 at the one or more predetermined angles while the metrology sub-system 102 collects spectral data from the illumination beam 202 and collected beam 210. In this regard, the symmetric positive and negative angular positions may enable the system 100 to capture complementary spectral information that may be analyzed to extract BCD data through extrapolation techniques.

For purposes of the present disclosure, the term “arcseconds” or “arcsec” may refer to a unit of angular measurement that represents a subdivision of degrees used in precision angular positioning and measurement applications. An arcsecond may be defined as 1/3600 of a degree, where one (1) degree contains 60 arcminutes and each arcminute contains 60 arcseconds. In some cases, arcseconds may be used to specify very small angular displacements or rotations that require high precision control. For example, one (1) arcsecond may correspond to an angular measurement that is approximately 4.85 microradians. The arcsecond unit may be particularly suitable for describing the fine angular adjustments used in tilt-based reflectometry measurements, where small changes in sample orientation can produce measurable variations in spectral signatures.

The sample stage 106 may include, but is not limited to, one or more actuators, one or more positioning mechanisms, and/or one or more control systems that work together to provide angular control across multiple axes of rotation. The one or more actuators may include any type of actuator such as, but not limited to, one or more piezoelectric actuators, stepper motors, servo motors, voice coil actuators, or the like that provide the mechanical force needed to achieve angular positioning of the sample 104. The one or more positioning mechanisms may include any type of precision mechanical components such as, but not limited to, one or more flexure stages, gimbal mounts, or multi-axis rotation stages configured to translate the actuator motion into controlled angular displacement of the sample 104. In some cases, the positioning mechanisms may also include encoder systems or position feedback sensors that provide real-time monitoring of the angular position to ensure accurate positioning and enable closed-loop control. The one or more control systems may include electronic controllers, feedback circuits, and software algorithms that coordinate the operation of the actuators and positioning mechanisms to achieve the desired angular positions. For example, the control systems may implement proportional-integral-derivative (PID) control algorithms or other advanced control strategies to maintain precise positioning while compensating for external disturbances or system variations.

In some embodiments, the illumination beam 202 itself may be directed at an angle relative to the sample surface, while maintaining the sample 104 in a fixed position. For example, the illumination focusing element 204 and illumination beam conditioning components 206 within the illumination pathway 208 may be configured to adjust the beam angle or direction to achieve the predetermined non-zero AOI. For instance, the illumination focusing element 204 and illumination beam conditioning components 206 may include various adjustable elements that enable precise control over the beam angle and direction.

For example, the illumination beam conditioning components 206 may include adjustable mirrors or beam steering mirrors that can be repositioned to redirect the illumination beam 202 at specific angles relative to the sample surface. In some cases, these mirrors may be mounted on motorized or piezoelectric actuators that provide fine angular control under the direction of the one or more controllers 108. By way of another example, the illumination beam conditioning components 206 may also include adjustable prisms or wedge prisms configured to deflect the illumination beam 202 by one or more predetermined angles, where the prism orientation or position may be modified to achieve the desired AOI. By way of another example, the illumination focusing element 204 may include adjustable beam expanders or collimators configured to modify both the beam size and angular characteristics simultaneously, providing additional flexibility in optimizing the measurement conditions for specific sample geometries. By way of another example, the illumination beam conditioning components 206 may include adjustable apertures or field stops that can be repositioned to control the illumination beam path and ensure proper beam alignment at various angles of incidence. By way of another example, the illumination beam conditioning components 206 may include adjustable polarization optics, such as rotatable polarizers or wave plates, that can be oriented to adjust the polarization state of the illumination beam 202 for enhanced measurement sensitivity at specific tilt angles.

In some embodiments, the system 100 may adjust the predetermined AOI by tilting the illumination source 200 at an angle relative to an axis of the sample 104. For example, the illumination source 200 may be repositioned to direct the illumination beam 202 toward the sample 104 at the predetermined non-zero AOI. For instance, the illumination source 200 may be mounted on a positioning assembly that enables controlled angular adjustment relative to the sample 104. In some cases, the positioning assembly may include motorized rotation stages, goniometers, or multi-axis positioning systems that provide precise control over the illumination source orientation. In this regard, the positioning assembly may be configured to rotate the illumination source 200 about one or more axes to achieve the desired AOI while maintaining proper optical alignment with the sample 104.

In some embodiments, the illumination source 200 may be coupled to a tilting mechanism that enables adjustment of the source position in real-time during measurement sequences. The tilting mechanism may include servo-controlled actuators or stepper motor assemblies that provide fine angular resolution comparable to the sample stage positioning capabilities. For example, the illumination source positioning may achieve angular adjustments with precision of +/−1 arcsecond or better, enabling synchronized angular variations with the sample positioning system.

It is contemplated herein that a combination of the above examples may be used to achieve the predetermined AOI. For example, the tilting approach may involve combinations of these methods, where both the sample positioning and illumination beam direction (e.g., through adjustment of illumination beam source or illumination optic elements) may be adjusted simultaneously based on predetermined measurement conditions associated with specific structural characteristics or measurement objectives. As such, the flexibility in achieving tilted measurement configurations through combined approaches may enable the system 100 to accommodate various sample types, structural geometries, and measurement requirements while maintaining the optical performance needed for accurate BCD determinations.

It is contemplated herein that a combination of the above examples may be used to achieve the predetermined AOI. For example, the tilting approach may involve combinations of these methods, where both the sample positioning and illumination beam direction (e.g., through adjustment of illumination beam source or illumination optic elements) may be adjusted simultaneously based on predetermined measurement conditions associated with specific structural characteristics or measurement objectives. As such, the flexibility in achieving tilted measurement configurations through combined approaches may enable the system 100 to accommodate various sample types, structural geometries, and measurement requirements while maintaining the optical performance needed for accurate BCD determinations.

Once the illumination beam 202 has been directed toward the sample 104 at the predetermined AOI through any of the aforementioned tilting approaches, the optical interaction between the illumination and the sample structure may generate spectral information that can be collected and analyzed for BCD measurements. For example, when the illumination beam 202 interacts with the sample 104, a collected beam 210 may be generated that contains spectral information about the sample structure. For example, the collected beam 210 may carry spectral signatures that are characteristic of the structural features within the sample 104, including information about both surface and sub-surface elements. In some instances, the spectral content of the collected beam 210 may be influenced by the interaction of the illumination beam 202 with various layers, interfaces, and geometric features present in the sample 104. For example, the collected beam 210 may contain reflectance information that varies as a function of wavelength, where different wavelengths may interact differently with the structural features of the sample 104.

In embodiments where the sample 104 includes high aspect ratio structures such as TSVs, the collected beam 210 may contain spectral information that is sensitive to the bottom critical dimensions of these structures. In this regard, the tilted angle of incidence may enable the illumination beam 202 to interact with sidewall surfaces and bottom features of the high aspect ratio structures in ways that would not be possible under normal incidence conditions of the existing methodologies. As a result, the collected beam 210 may exhibit spectral characteristics that provide enhanced sensitivity to BCD variations. The spectral content of the collected beam 210 may also be influenced by the specific tilt angle employed during the measurement. For example, it is noted herein that different tilt angles may produce different interaction patterns between the illumination beam 202 and the sample structure, resulting in collected beams 210 with varying spectral signatures. In some cases, measurements performed at multiple tilt angles may generate a series of collected beams 210, each containing complementary spectral information that may be analyzed collectively to extract bottom critical dimension data. The collected beam 210 may also contain information about other structural parameters of the sample 104, such as sidewall angles, surface roughness, and material properties. The multi-angle measurement approach may enable the collected beam 210 to capture spectral data that allows for decorrelation of these various structural parameters, thereby providing more comprehensive characterization capabilities than conventional single-angle measurement techniques.

The collected beam 210 may propagate along a collected pathway 212 that directs the collected beam 210 toward collection components of the metrology sub-system 102. For example, the collected pathway 212 may include a collection focusing element 214 that focuses or collimates the collected beam 210 to improve detection efficiency and measurement accuracy. By way of another example, the collected pathway 212 may include one or more collection beam conditioning elements 216 that may modify properties of the collected beam 210 before detection/collection. In some cases, the collection beam conditioning elements 216 may include polarization analyzers, spectral filters, or other optical components that improve the measurement sensitivity or selectivity. Referring to FIG. 2B, the metrology sub-system 102 may further include a beamsplitter 220 positioned within the optical system to separate the illumination pathway 208 from the collected pathway 212. Further, as shown in FIG. 2B, the metrology sub-system 102 may further include an objective lens 222 that may be positioned between the beamsplitter 220 and the sample 104 to provide focusing and collection functions for both the illumination beam 202 and collected beam 210.

The one or more detectors 218 may be configured to provide spectral resolution that enables discrimination of wavelength-dependent features in the collected beam 210, thereby facilitating analysis of the spectral signatures associated with bottom critical dimensions. The one or more detectors 218 may be configured to receive and convert the collected beam 210 into electrical signals that represent the spectral characteristics of the light emanating from the sample 104. It is contemplated herein that the one or more detectors 218 may include any type of detector such as, but not limited to, one or more photodetectors, photodiode arrays, one or more charge-coupled devices (CCDs), one or more complementary metal-oxide-semiconductor (CMOS) sensors, or the like capable of measuring optical signals across a predetermined wavelength range.

The one or more detectors 218 may be communicatively coupled to the one or more controllers 108. For example, the collection signals generated by the one or more detectors 218 may be amplified, filtered, or digitized before transmission to the one or more controllers 108 for analysis. By way of another example, the one or more detectors 218 may include calibration signals that enable correction for detector response variations, dark current effects, or other systematic measurement errors that could affect the accuracy of BCD determinations.

In embodiments, the one or more controllers 108 may be configured to receive and process metrology data collected from the one or more detectors 218 at multiple tilt angles to determine BCD values through computational analysis techniques. For example, the one or more controllers 108 may implement data processing algorithms that analyze spectral reflectometry measurements obtained at various angular positions of the sample 104 or the illumination beam 202. For instance, the one or more controllers 108 may coordinate the collection of measurement data across a predetermined sequence of tilt angles, where each angular position may provide spectral information that contributes to the overall analysis of BCDs. In this regard, the one or more controllers 108 may store the collected metrology data in memory 112 and apply mathematical processing techniques to extract structural information from the spectral signatures obtained at the different AOIs.

In embodiments, the one or more controllers 108 may extrapolate BCD values at zero-degree incidence based on the metrology data obtained at non-zero AOIs. For example, the one or more controllers 108 may use one or more linear fitting algorithms that establish mathematical relationships between the measured spectral parameters and the corresponding tilt angles. The linear fitting process may involve least squares regression analysis where spectral parameters such as reflectance amplitude, phase shift, or polarization ratios are plotted as functions of tilt angle.

In a non-limiting example, the one or more linear fitting algorithms may include one or more linear polarization analysis (LPA) algorithms that analyze polarization-dependent spectral signatures obtained at different tilt angles. The LPA algorithms may calculate polarization n ratios between s-polarized and p-polarized reflectance measurements collected at each tilt angle, where the polarization ratio (i.e., R_p/R_s) varies linearly with tilt angle according to Fresnel reflection coefficients (which describe the amplitude and phase relationships of reflected electromagnetic waves at interfaces between materials with different refractive indices). For instance, the LPA algorithms may calculate polarization ratios or phase differences between s-polarized and p-polarized reflectance measurements collected at each tilt angle, where the linear fitting algorithm may establish a mathematical relationship between the polarization-dependent spectral parameters and the corresponding tilt angles. The relationship may be expressed as a linear function given by Equation 1 below:

$$y = m x + b \qquad Eqn . 1$$

where y represents the spectral parameter (such as In(R_p/R_s)), x represents the tilt angle in arcseconds, m represents the slope coefficient (typically ranging from 0.001 to 0.1 per arcsecond), and b represents the y-intercept corresponding to the zero-degree incidence value. The fitting algorithm may include statistical analysis to determine correlation coefficients, standard errors, and confidence intervals for the extrapolated values. In this regard, the one or more controllers 108 may use the fitted linear model to predict the spectral characteristics that would be observed at zero-degree incidence, thereby enabling determination of BCD values under normal incidence conditions based on metrology data collected at the non-zero angles of incidence.

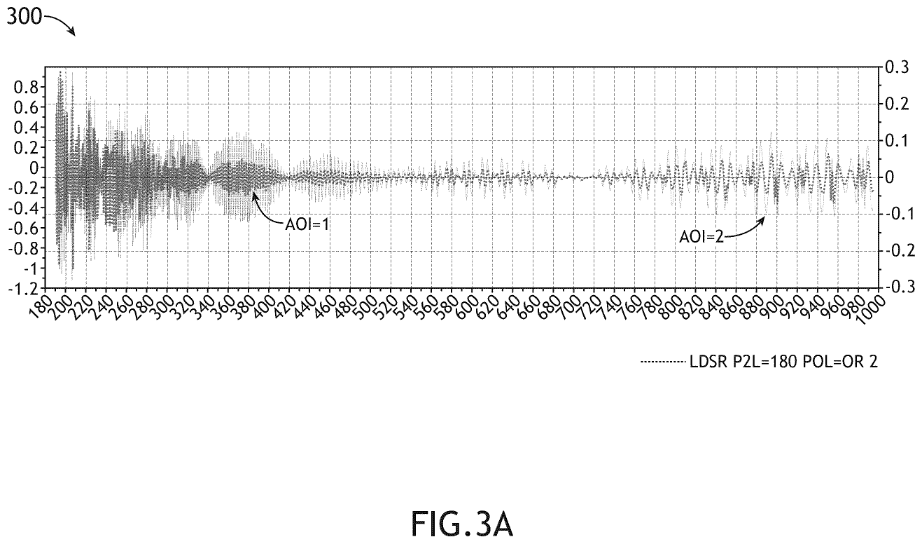

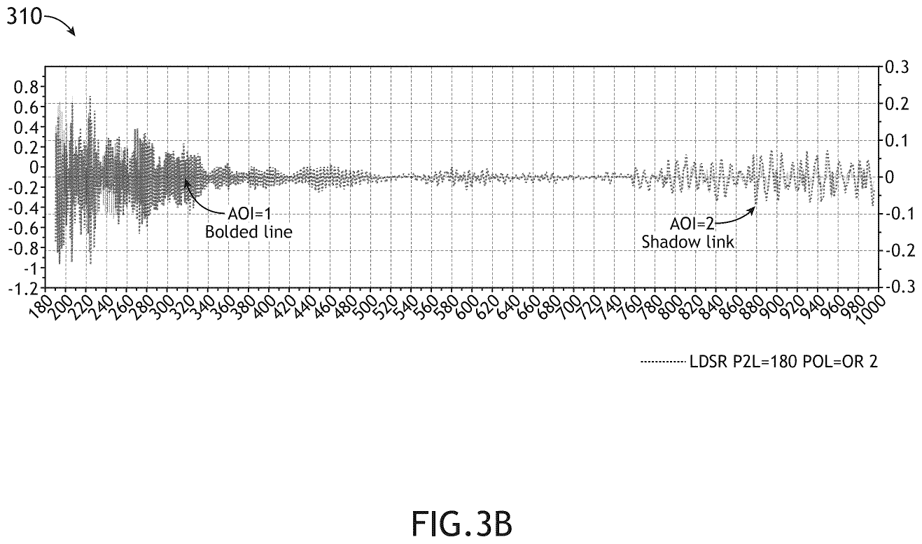

In embodiments, the one or more controllers 108 may analyze spectral differences between tilted and non-tilted measurements to determine bottom rounding degree characteristics of the sample structures using quantitative analysis methods. For example, the one or more controllers 108 may compare spectral signatures obtained at various tilt angles with reference measurements collected at zero-degree incidence to identify spectral delta patterns that correlate with structural geometry. The analysis may involve calculating spectral difference functions, shown and described by Equation 2 below:

$$Δ ( λ , θ ) = R ( λ , θ ) - R ( λ , 0 ) \qquad Eqn . 2$$

where R(λ, θ) represents reflectance as a function of wavelength λ and tilt angle θ. As illustrated in FIG. 3A, flat bottom structures exhibit larger spectral deltas between tilted and non-tilted measurements compared to rounded bottom structures, with delta amplitudes typically 2-5 times larger for flat structures. In some cases, the one or more controllers 108 may determine that flat bottom structures produce more pronounced spectral variations across different AOI measurements, as demonstrated by the amplitude differences shown in plot 300 of FIG. 3A, where spectral delta magnitudes may exceed 0.1 in normalized reflectance units. The analysis may include Fourier transform analysis of the spectral delta patterns to identify characteristic frequencies associated with structural geometry. Conversely, as shown in FIG. 3B, rounded bottom structures exhibit smaller spectral deltas across tilt angles, where plot 310 demonstrates that rounding BCD has less spectral delta across the tilt angle, typically showing delta amplitudes 50-80% smaller than flat structures. The one or more controllers 108 may quantify these spectral differences by calculating amplitude variations, phase shifts, root-mean-square (RMS) values of spectral deltas, or other spectral parameters that change as a function of tilt angle. The quantification may include statistical metrics such as standard deviation of spectral deltas, correlation coefficients between different tilt angle measurements, and spectral contrast ratios. The analysis of spectral deltas may enable the one or more controllers 108 to characterize the degree of bottom rounding in high aspect ratio structures, where the reduced spectral variations observed in rounded features, as depicted in FIG. 3B, can be used as a quantitative factor to estimate the BCD rounding radius (typically ranging from 5-50 nanometers) and decorrelate the BCD rounding parameter in the regression analysis through multivariate fitting algorithms.

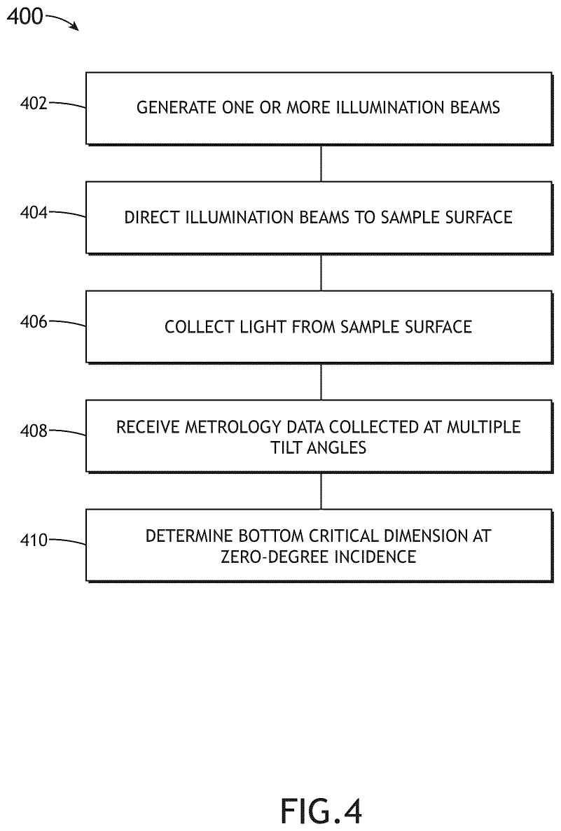

FIG. 4 illustrates a flowchart depicting a method 400 for measuring bottom critical dimensions, in accordance with one or more embodiments of the present disclosure.

In embodiments, the method 400 may include a step 402 of generating one or more illumination beams. For example, the illumination source 200 may be configured generate the one or more illumination beams 202 with spectral characteristics suitable for tilt-based reflectometry measurements of high aspect ratio structures. For instance, the one or more illumination beams 202 may include broadband illumination that spans multiple wavelengths to enable comprehensive spectral analysis of the sample 104. The illumination beam 202 may be conditioned through the illumination focusing element 204 and the illumination beam conditioning components 206 to achieve appropriate beam properties for the measurement sequence. The generation of the illumination beam 202 may be controlled by the controller 108, where the processors 110 may execute program instructions stored in the memory 112 to coordinate the timing and characteristics of the illumination generation with other components of the system 100.

In embodiments, the method 400 may include a step 404 of directing one or more illumination beams to a surface of the sample 104. For example, the illumination beam 202 may be directed along the illumination pathway 208 toward the sample 104 positioned on the sample stage 106. In some cases, the AOI may be achieved by tilting the sample stage 106 to position the sample 104 at a predetermined angular orientation relative to the illumination beam 202. For instance, the sample stage 106 may provide precise angular control of the tilt angle of the sample 104, where the sample 104 may be measured at a plurality of tilt angles between 1-2000 arcseconds. By way of another example, the AOI may be achieved by adjusting the direction of the illumination beam 202 through the repositioning of the one or more illumination optical components within the illumination pathway 208. By way of another example, the AOI may be achieved by adjusting the position of the illumination source 200. In this regard, the one or more controllers 108 may be configured to control the positioning of the sample stage 106 or the illumination beam direction to achieve the predetermined AOI for each measurement in the sequence.

In embodiments, the method 400 may include a step 406 of collecting the light emanating from the surface of the sample. For example, when the illumination beam 202 interacts with the sample 104 at the predetermined AOI, the collected beam 210 may be generated that contains spectral information characteristic of the structural features within the sample 104. The collected beam 210 may propagate along the collected pathway 212, where the collection focusing element 214 may focus or collimate the collected beam 210 to improve detection efficiency. In some cases, the collection beam conditioning elements 216 may modify properties of the collected beam 210, such as polarization state or spectral content, to enhance measurement sensitivity for bottom critical dimension analysis. The collected beam 210 may pass through the objective lens 222 and beamsplitter 220 in configurations where these optical components are present within the metrology sub-system 102. The directing and collecting of the light may be synchronized with the illumination generation and sample positioning to ensure consistent measurement conditions across the plurality of tilt angles.

In embodiments, the method 400 may include a step 408 of receiving from the one or more detectors a set of metrology data based on the collected light, where the set of metrology data includes metrology measurement data collected at the plurality of tilt angles. For example, the one or more detectors 218 may be configured to convert the collected beam 210 into electrical signals that represent the spectral characteristics of the light emanating from the sample 104 at each respective tilt angle. In some cases, the metrology measurement data may include spectral reflectometry information collected at multiple angular positions. The one or more controllers 108 may then receive the metrology data through signal processing circuits that amplify, filter, or digitize the detector signals before storage in the memory 112. The set of metrology data may include spectral amplitude information, phase data, and polarization-dependent measurements that vary as a function of both wavelength and tilt angle.

In embodiments, the method 400 may include a step 410 of determining a BCD value at zero-degree incidence based on the set of metrology data received at non-zero AOIs. For example, the one or more controllers 108 may be configured to analyze the spectral reflectometry measurements obtained at the various angular positions using one or more linear fitting algorithms. For instance, the one or more processors 110 may execute the one or more linear fitting algorithms to establish a mathematical relationship between the measured spectral parameters and the corresponding tilt angles, such that the one or more processors 110 may extrapolate the BCD values obtained at non-zero AOIs to BCD values that would be observed under normal incidence conditions where AOI=0. Further, the determination may involve analysis of spectral differences between measurements collected at different tilt angles, where flat bottom structures exhibit larger spectral deltas compared to rounded bottom structures, as demonstrated in the plot 300 and plot 310 shown in FIGS. 3A-3B, respectively.

In embodiments, the method 400 may extend to the system technologies described herein, including the system 100, the metrology sub-system 102, and associated components such as the sample stage 106, illumination source 200, and controller 108. The method 400 may be implemented using various configurations of optical components, detection systems, and control algorithms that enable tilt-based reflectometry measurements. However, the method 400 may not be limited to any particular system architecture, and may be adapted for use with different metrology platforms, illumination sources, or detection schemes that provide the capability to perform spectral measurements at multiple tilt angles and analyze the resulting data to determine bottom critical dimensions through extrapolation techniques.

Any of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A metrology system comprising:
an illumination source configured to generate one or more illumination beams;
one or more illumination optics configured to direct the one or more illumination beams to a surface of a sample disposed on a sample stage, wherein the one or more illumination beams have a non-zero angle of incidence with respect to the surface of the sample;
one or more detectors configured to collect light emanated from the surface of the sample;
one or more collection optics configured to direct the light emanated from the surface of the sample to the one or more detectors; and
a controller communicatively coupled to the one or more detectors, wherein the controller includes one or more processors configured to execute a set of program instructions stored in memory, wherein the set of program instructions are configured to cause the one or more processors to:
receive a set of metrology data from the one or more detectors based on the collected light, wherein the set of metrology data includes metrology measurement data collected at a plurality of tilt angles based on the non-zero angle of incidence; and
determine a bottom critical dimension value at zero-degree angle of incidence by extrapolating the metrology measurement data collected at the plurality of tilt angles based on the non-zero angle of incidence.

2. The metrology system of claim 1, further comprising:
the sample stage.

3. The metrology system of claim 2, wherein the sample stage includes a multi-axis tilting stage configured to tilt the sample in at least one of an x-direction or a y-direction based on the plurality of tilt angles.

4. The metrology system of claim 1, wherein the one or more illumination optics include one or more adjustable beam steering components configured to direct the one or more illumination beams at one or more predetermined non-zero angles relative to a surface normal of the sample.

5. The metrology system of claim 1, wherein the plurality of tilt angles are between 10 arcseconds and 50 arcseconds.

6. The metrology system of claim 1, wherein the metrology system comprises a spectral reflectometry metrology system configured to measure reflectance information that varies as a function of wavelength.

7. The metrology system of claim 1, wherein the sample comprises a substrate.

8. The metrology system of claim 7, wherein the substrate comprises a wafer.

9. The metrology system of claim 1, the one or more processors are configured to:
apply one or more linear fitting algorithms to extrapolate the metrology measurement data, wherein the one or more linear fitting algorithms comprise linear polarization analysis algorithms that analyze polarization-dependent spectral signatures obtained at the plurality of tilt angles.

10. The metrology system of claim 1, wherein the one or more processors are further configured to:
compare spectral signatures obtained at the plurality of tilt angles to identify spectral delta patterns, wherein flat bottom structures exhibit larger spectral deltas compared to rounded bottom structures.

11. A system comprising:
a controller communicatively coupled to a metrology sub-system, wherein the controller includes one or more processors configured to execute a set of program instructions stored in memory, wherein the set of program instructions are configured to cause the one or more processors to:
receive a set of metrology data from the metrology sub-system, wherein the set of metrology data includes metrology measurement data for a sample disposed on a sample stage collected at a plurality of tilt angles based on a non-zero angle of incidence; and
determine a bottom critical dimension value at zero-degree angle of incidence by extrapolating the metrology measurement data collected at the plurality of tilt angles based on the non-zero angle of incidence.

12. The system of claim 11, further comprising:
an illumination sub-system comprising:
an illumination source configured to generate one or more illumination beams; and
one or more illumination optics configured to direct the one or more illumination beams to a surface of the sample, wherein one or more illumination beams have the non-zero angle of incidence with respect to the surface of the sample.

13. The system of claim 12, further comprising:
a collection sub-system comprising:
one or more detectors configured to collect light emanated from the surface of the sample; and
one or more collection optics configured to direct the light emanated from the surface of the sample to the one or more detectors.

14. The system of claim 13, further comprising:
the sample stage, wherein the sample stage includes a multi-axis tilting stage configured to tilt the sample in at least one of an x-direction or a y-direction based on the plurality of tilt angles.

15. The system of claim 12, wherein the one or more illumination optics include one or more adjustable beam steering components configured to direct the one or more illumination beams at one or more predetermined non-zero angles relative to a surface normal of the sample.

16. The system of claim 11, wherein the plurality of tilt angles are between 10 arcseconds and 50 arcseconds.

17. The system of claim 11, wherein the metrology sub-system comprises a spectral reflectometry metrology system configured to measure reflectance information that varies as a function of wavelength.

18. The system of claim 11, wherein the sample comprises a substrate.

19. The system of claim 18, wherein the substrate comprises a wafer.

20. The system of claim 11, the one or more processors are configured to:
apply one or more linear fitting algorithms to extrapolate the metrology measurement data, wherein the one or more linear fitting algorithms comprise linear polarization analysis algorithms that analyze polarization-dependent spectral signatures obtained at the plurality of tilt angles.

21. The system of claim 11, wherein the one or more processors are further configured to:
compare spectral signatures obtained at the plurality of tilt angles to identify spectral delta patterns, wherein flat bottom structures exhibit larger spectral deltas compared to rounded bottom structures.

22. A method comprising:
generating one or more illumination beams;
directing the one or more illumination beams to a surface of a sample disposed on a sample stage, wherein the one or more illumination beams have a non-zero angle of incidence with respect to the surface of the sample;
directing light emanating from the surface of the sample to one or more detectors;
collecting light emanated from the surface of the sample using the one or more detectors;
receiving a set of metrology data from the one or more detectors based on the collected light, wherein the set of metrology data includes metrology measurement data collected at a plurality of tilt angles based on the non-zero angle of incidence; and
determining a bottom critical dimension value at zero-degree angle of incidence by extrapolating the metrology measurement data collected at the plurality of tilt angles based on the non-zero angle of incidence.
